(19) United States
(12) Patent Application Publication
(10) Pub. No.: US 2007/0024477 A1
(43) Pub. Date: Feb. 1, 2007

(54) DPSK demodulator and method

(76) Inventors: Changqing Xu, Singapore (SG); Zhiping Li, Singapore (SG); Tingwu Wang, Singapore (SG); Masayuki Tomisawa, Singapore (SG)

Correspondence Address: QUARLES & BRADY LLP, 411 E. WISCONSIN AVENUE, SUITE 2040, MILWAUKEE, WI, 53202-4497, US

(21) Appl. No.: 11/481,663

(22) Filed: Jul. 6, 2006

(30) Foreign Application Priority Data
Jul. 6, 2005 (SG) SG 200504852-5

(51) Int. Cl. H03M 3/00

(52) U.S. Cl. 341/143

(57) ABSTRACT

There is provided a method and apparatus for demodulating a received hard limited DPSK signal, which may be an intermediate frequency (IF) signal. The apparatus comprises: a digital down converter for generating an in-phase component I and a quadrature component Q of a received signal; at least one decimator for reducing sampling frequency of the received signal; at least one filter for reducing noise outside a required bandwidth; and a differential decoder for performing differential detection of I and Q over a given symbol span. The method comprises the steps of: generating an in-phase component I and a quadrature component Q from a received signal; reducing sampling frequency of the received signal; reducing noise outside a required bandwidth; and performing differential detection of I and Q over a given symbol span.

### FIELD OF THE INVENTION

The invention relates to an apparatus and method for demodulating a received IF DPSK signal.

### BACKGROUND OF THE INVENTION

Phase Shift Keying (PSK) and Differential Phase Shift Keying (DPSK) modulation schemes are widely used in wireless communication. In DPSK, the phase of the carrier is discretely varied in relation to the phase of the immediately preceding signal element in accordance with the data being transmitted. Differential Quadrature Phase Shift Keying (DQPSK) and Differential Bi-Phase Shift Keying (DBPSK) are other variations.

DQPSK is often employed in wireless Local Area Network (WLAN) systems, 8DPSK is used in some Bluetooth medium rate systems and

$$\frac{π}{4} DQPSK$$

is used in a number of applications including Time Division Multiple Access (TDMA) systems, IS-54 and IS-136 (which are two standards of cellular systems deployed in the United States, IS-54 being the US TDMA standard with an analog control channel and IS-136 being the US TDMA standard with a digital control channel), some Bluetooth medium rate systems, PHS (“Personal Handy Phone System”, ARIB Standard, Version 4.0, February 2003), Inter-Vehicle Communication (IVC) and Terrestrial Trunked Radio (TETRA) systems. Obviously, it is particularly important for the mobile stations used in wireless communication to limit power consumption as much as possible.

In traditional demodulators for DPSK signals, an analogue to digital converter (ADC) is used to convert the received analogue signal (either a baseband signal or an intermediate frequency (IF) signal) into digital form for further processing. One drawback of this arrangement is that ADCs typically consume a lot of power (which is particularly disadvantageous for mobile receivers). Another drawback is that the design and implementation costs are rather high because of the power-hungry ADC.

There have been several attempts to solve the problem of high power consumption and high design cost in traditional DPSK demodulators and some of these are described in U.S. Pat. No. 3,997,847, U.S. Pat. No. 5,122,758, U.S. Pat. No. 5,539,776, U.S. Pat. No. 5,640,427, U.S. Pat. No. 5,945,875 and “Digital Intermediate Frequency Demodulation Technique for Cellular Communication Systems”, Hideho TOMITA, Yukio YOKOYAMA, Toru MATSUKI, Global Telecommunications Conference, 1990, and Exhibition “Communications: Connecting the Future”, GLOBECOM '90, IEEE. All those designs DPSK demodulate an IF hard limited signal, the key technology being to use a counter for zero-crossing detection and to determine the phase difference using those counters. Because of this, no ADC is required since the digitization is performed by the hard limiter which generates a logical signal, which can take one of 2-levels (i.e. it is 1 bit), from the incoming analogue signal. No ADC is an advantage as the design complexity can be reduced, but there are some disadvantages with these systems. Firstly, a very high sampling rate (sometimes as high as 100 times the intermediate frequency) is required to ensure acceptable performance. This is because the hard limiter works as a 1-bit ADC and the counter is used to do phase difference detection. Thus, the arrangement is not very complex so, to compensate for the consequent low resolution, a very high sampling rate is necessary. This obviously means high power consumption. Secondly, the performance in terms of Bit Error Rate (BER) is actually much worse that traditional arrangements using an ADC. In fact, in the scheme described in “Digital Intermediate Frequency Demodulation Technique for Cellular Communication Systems” (mentioned above), the performance at a BER of 10⁻⁴ is about 3 dB worse than the performance of a traditional ADC arrangement.

### SUMMARY OF THE INVENTION

It is an object of the invention to provide a demodulator for DPSK signals and a method for demodulating DPSK signals which mitigate or substantially overcome the problems of known arrangements and methods described above.

According to the invention, there is provided apparatus for demodulating a received hard limited DPSK signal, the apparatus comprising:

a digital down converter (DDC) for generating an in-phase component I and a quadrature component Q of a received signal;

at least one decimator for reducing sampling frequency of the received signal;

at least one filter for reducing noise outside a required bandwidth; and

a differential decoder for performing differential detection of I and Q over a given symbol span.

Because the received signal is hard limited, no ADC is required, which reduces design complexity compared with traditional arrangements. In addition, inclusion of the DDC, decimator, filter and differential decoder means than the sampling rate can be reduced compared with known arrangements incorporating a hard limiter. Thus, both complexity and sampling rate are improved.

In one embodiment, the DDC is upstream of the at least one decimator and the at least one decimator comprises one decimator for the I component and one decimator for the Q component.

In another embodiment, the DDC is downstream of the at least one decimator and the at least one decimator comprises only one decimator for the received signal. This second embodiment is advantageous because only a single decimator is required. In addition, since the decimator is upstream of the DDC, the operating frequency of the DDC is reduced.

Preferably, the DDC is arranged to generate the in-phase component I by multiplying the received signal by a cosine function and to generate the quadrature component Q by multiplying the received signal by a sine function.

Preferably, the DDC operates at a frequency which is a predetermined number of times greater than the frequency of the received signal. In one embodiment, the DDC is arranged to operate at a frequency that is four times the frequency of the received signal, in which case the cosine function is simplified to the values {1, 0, −1, 0} over each cycle of the received signal and the sine function is simplified to the values {0, 1, 0, −1} over each cycle of the received signal. This allows the structure of the DDC to be simplified. Other simplifications could also be envisaged, for example if the operating frequency of the DDC were twice the frequency of the received signal.

In one arrangement, the or each of the at least one decimator comprises a cascaded integrator comb (CIC) filter. A CIC filter is advantageous for performing decimation since it does not include multipliers.

Preferably, the CIC filter comprises N integrator stages, N comb stages and a downsampler for reducing the sampling rate of the received signal. The down sampler may reduce the sampling rate by a factor of R. Each comb stage may introduce a delay of M to the CIC filter. The CIC filter may have the frequency response:

$$H ( ω ) = \frac{{( 1 - {ⅇ}^{- ⅈ RM ω} )}^{N}}{{( 1 - {z}^{- ⅈ ω} )}^{N}}$$

where ω is the frequency of the received signal.

In another arrangement, the or each of the at least one decimator is a finite impulse response (FIR) filter.

In one preferred embodiment, the or each of the at least one filter is arranged to perform pulse shaping of the received signal.

In that embodiment, the or each of the at least one filter may comprise all or part of a raised cosine filter.

In one case, the or each of the at least one filter may comprise a root raised cosine (RRC) filter. In that case, there will usually be at least one other RRC filter in the transmitter which transmitted the signals. The at least one RRC filter in the receiver together with the at least one RRC filter in the transmitter together provide raised cosine function pulse shaping of the signal. The or each RRC filter may comprise 49 taps.

In an alternative embodiment, the or each of the at least one filter may comprise a low pass filter.

The differential decoder may be arranged to perform differential detection of I and Q over a symbol span of one symbol. Of course, other symbol spans can also be envisaged.

In one embodiment, the differential decoder comprises a decision block for converting the differentially decoded I into an I output and for converting the differentially decoded Q into a Q output, the I output and the Q output each taking a value of either 0 or 1.

In that embodiment, the I decision may be: if the differentially decoded I is greater than zero, the I output is 0 and, if the differentially decoded I is less than zero, the I output is 1. In that embodiment, the Q decision may be: if the differentially decoded Q is greater than zero, the Q output is 0 and, if the differentially decoded Q is less than zero, the Q output is 1.

In one embodiment, the apparatus further comprises a hard limiter for hard limiting the received DPSK signal.

Preferably, the received signal is an intermediate frequency (IF) signal. Alternatively, the received signal may be a baseband signal.

In one embodiment, the received signal is

$$\frac{π}{4} DQPSK$$

modulated.

According to the invention, there is also provided a receiver for DPSK signals, the receiver comprising apparatus as described above.

According to the invention, there is also provided a method for demodulating a received hard limited DPSK signal, the method comprising the steps of:

a) generating an in-phase component I and a quadrature component Q from a received signal;

b) reducing sampling frequency of the received signal;

c) reducing noise outside a required bandwidth; and

d) performing differential detection of I and Q over a given symbol span.

In a first embodiment, step a) is performed before step b) and step b) comprises the steps of reducing sampling frequency of the in-phase component I and reducing sampling frequency of the quadrature component Q.

In a second embodiment, step a) is performed after step b). The second embodiment is advantageous because only a single decimating step is required for the entire received signal rather than separate decimating steps for I and for Q.

Preferably, step a) comprises multiplying the received signal by a cosine function to generate the in-phase component I and multiplying the received signal by a sine function to generate the quadrature component Q.

Step a) of the method may be performed in a digital down converter (DDC).

Step b) of the method may be performed in a cascaded integrator comb (CIC) filter. A CIC filter is advantageous for performing decimation since it does not includes multipliers. Preferably, the CIC filter comprises N integrator stages, N comb stages and a down sampler for reducing the sampling rate. The down sampler may reduce the sampling rate by a factor of R. Each comb stage may introduce a time delay of M to the CIC filter.

Alternatively, step b) of the method may be performed in a single finite impulse response (FIR) filter.

Step c) of the method may be performed in a low pass filter.

In one embodiment, the method further comprises the step of pulse shaping the received signal.

In that embodiment, in a first case, the step of reducing noise outside the required bandwidth and the step of pulse shaping the received signal may both be performed in a raised cosine filter.

Alternatively, in a second case, the step of reducing noise outside the required bandwidth and the step of pulse shaping the received signal may be performed in a root raised cosine (RRC) filter. In the second case, there will usually be at least one other RRC filter in a transmitter which transmitted the signals.

Step d) may comprise performing differential detection of I and Q over a symbol span of one symbol.

The method may further comprise the steps of converting the differentially decoded I into an I output and converting the differentially decoded Q into a Q output, the I output and the Q output each taking a value of either 0 or 1. In that case, it may be set that, if the differentially decoded I is greater than zero, the I output is 0 and, if the differentially decoded I is less than zero, the I output is 1. Also, in that case, it may be set that, if the differentially decoded Q is greater than zero, the Q output is 0 and, if the differentially decoded Q is less than zero, the Q output is 1.

In one embodiment, the method further comprises, before step a), the step of hard limiting the received DPSK signal.

Preferably, the received signal is an intermediate frequency (IF) signal. Alternatively, the received signal may be a baseband signal.

The received signal may be

$$\frac{π}{4} DQPSK$$

modulated.

According to the invention there is also provided apparatus for carrying out the method described above.

According to the invention there is also provided a receiver for DPSK signals, for carrying out the method described above.

Features described in relation to the apparatus of the invention may also be applicable to the method of the invention and features described in relation to the method of the invention may also be applicable to the apparatus of the invention.

### BRIEF DESCRIPTION OF THE DRAWINGS

By way of example, preferred embodiments of the invention will now be described with reference to the accompanying drawings, of which:

FIG. 1 is a diagram of a demodulator according to a first embodiment of the invention;

FIG. 2 is a detailed diagram of block 103 of FIG. 1;

FIG. 3 is a detailed diagram of blocks 105a and 105b of FIG. 1

FIG. 4 is a detailed diagram of blocks 107a and 107b of FIG. 1;

FIG. 5 is a graph showing performance of the demodulator of FIG. 1 at three different sampling rates;

FIG. 6 is a diagram of a demodulator according to a second embodiment of the invention;

FIG. 7 is a detailed diagram of block 605 of FIG. 6;

FIG. 8 is a graph showing performance of the demodulators of FIGS. 1 and 6; and

FIG. 9 is a diagram of a demodulator according to a third embodiment of the invention.

### DETAILED DESCRIPTION OF PREFERRED EMBODIMENTS

All the described embodiments show demodulators for

$$\frac{π}{4} DQPSK ,$$

but the invention is not limited to

$$\frac{π}{4} DQPSK$$

and could apply to any differentially encoded PSK signal. Also, for all three described demodulators, the input is a 2-level (i.e. 1 bit) IF signal from an IF hard limiter. However, although the major application of the invention is IF signals, the invention could also be used with baseband.

FIG. 1 shows a block diagram of a

$$\frac{π}{4} DQPSK$$

demodulator 101 according to a first embodiment of the invention. The demodulator includes a Digital Down Converter (DDC) 103, Cascaded Integrator Comb (CIC) filters 105a and 105b, Root Raised Cosine (RRC) filters 107a and 107b, a differential decoder 109 and a decision block 111. The input to the demodulator 101 is a 2-level (i.e. 1 bit) IF signal from an IF hard limiter (not shown). The outputs of the demodulator 101 are I and Q signals.

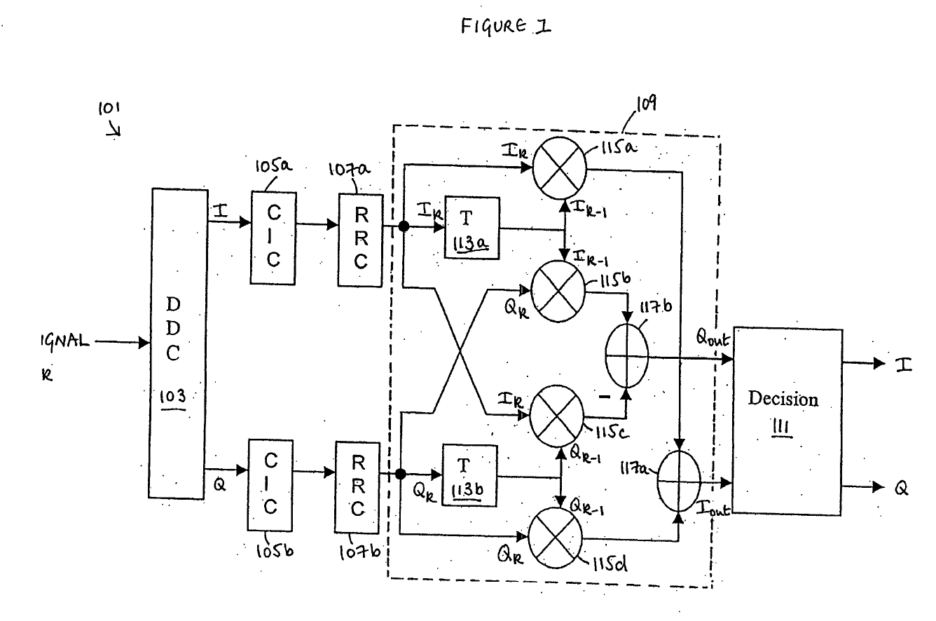

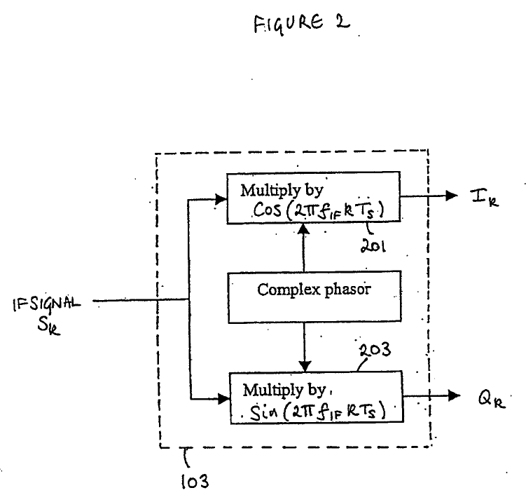

FIG. 2 shows the DDC 103 of FIG. 1 in more detail. Digital down conversion is used to recover the in-phase component I and the quadrature component Q from the received IF signal. The IF signal can be expressed as:
Sₖ=Aₖ cos{2πf_{IF}kTₛ+φₖ}
where k is the sample number (also known as the order), Aₖ is amplitude of the sampled IF signal at sample k, f_{IF} is the intermediate frequency, Tₛ is the time between one sample and the next i.e. the sampling interval and φₖ is the phase of the sampled IF signal at sample k.

Tₛ (which is equal to

$$\frac{1}{{f}_{s}} ,$$

fₛ being the sampling frequency) is chosen so that fₛ is as low as possible to still obtain acceptable performance in the demodulator given f_{IF}. We can obtain acceptable performance with this arrangement with a sampling frequency fₛ much lower than the sampling frequency in known arrangements which use a hard limiter to digitize the incoming signal, as discussed previously. This is because, by sacrificing some of the reduced complexity of known hard limiter arrangements, we can obtain a huge decrease in required sampling rate.

As shown in FIG. 2, the I channel is formed by multiplying Sₖ by cos{2πf_{IF}kTₛ} at block 201 and the Q channel is formed by multiplying Sₖ by sin{2πf_{IF}kTₛ} at block 203. The resulting I and Q components therefore have the form:
Iₖ=Aₖ cos{2πf_{IF}kTₛ+φₖ}cos{2πf_{IF}kTₛ}
and
Qₖ=Aₖ cos{2πf_{IF}kTₛ+φₖ}sin{2πf_{IF}kTₛ}

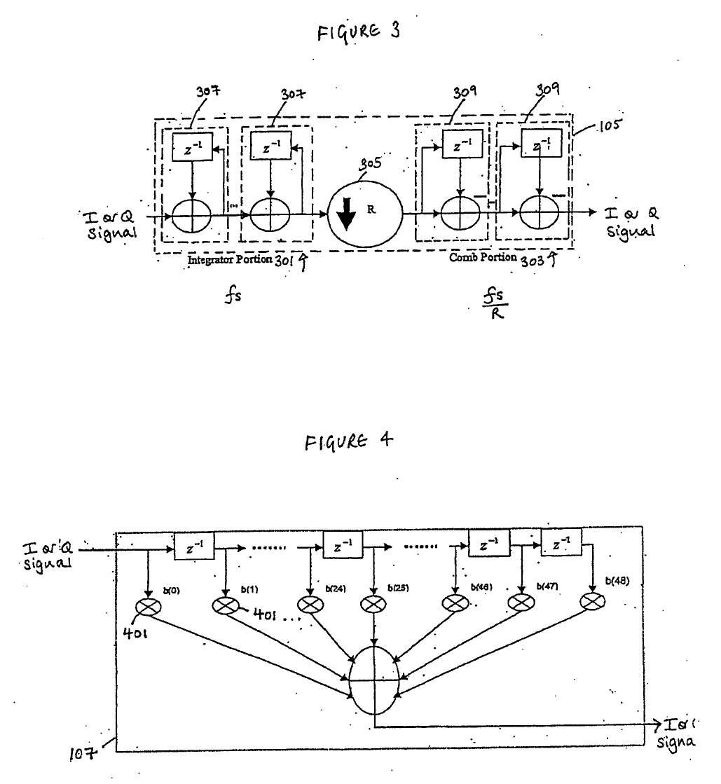

FIG. 3 shows each CIC filter 105a, 105b of FIG. 1 in more detail. The CIC filters are used to perform decimation. A CIC filter is very efficient for performing decimation (or interpolation) since it does not contain multipliers.

As shown in FIG. 3, each CIC filter 105a, 105b comprises an integrator portion 301 and a comb portion 303. Between the integrator portion 301 and the comb portion 303 there is a down sampler 305 for reducing the sampling rate by a factor R. The integrator portion comprises N integrator stages 307 clocked at rate

$${f}_{s} = \frac{1}{{T}_{s}} .$$

As is well known, each integrator stage is simply an infinite impulse response (IIR) filter which acts like a low pass filter. The comb portion comprises N comb stages 309 clocked at rate

$$\frac{{f}_{s}}{R} = \frac{1}{{RT}_{s}} .$$

Similarly, each comb stage is simply a finite impulse response (FIR) filter which acts like a high pass filter.

The CIC filter may have the frequency response:

$$H ( ω ) = \frac{{( 1 - {ⅇ}^{- ⅈ RM ω} )}^{N}}{{( 1 - {ⅇ}^{- ⅈω} )}^{N}}$$

where ω is the frequency of the received signal and M is the time delay at each comb stage of the CIC filter.

To reduce the power consumption of the subsequent RRC filter 107, the higher the decimation rate of the CIC filter 105, the better. However, greater decimation obviously means some degradation in performance. Thus, a compromise must be found between low sampling rate in the RRC and good BER performance of the demodulator. So, we choose R, M and N appropriately for the required frequency response of the CIC filter.

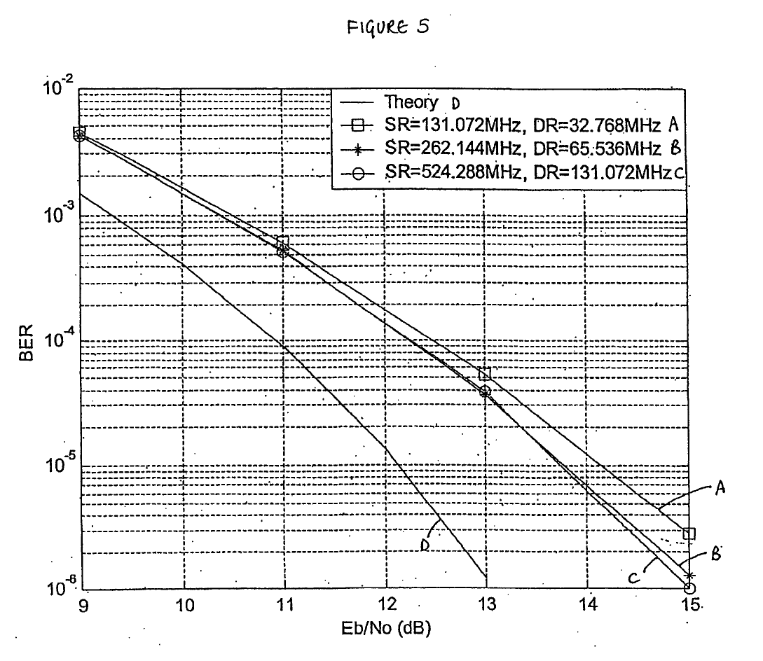

FIG. 4 shows each RRC filter 107a, 107b of FIG. 1 in more detail. In this embodiment, RRC filters are used in the receiver since there will also be RRC filters (not shown) in the transmitter, meaning that the overall pulse shaping follows the raised cosine function (since the overall effect of the two filters is the product of the two functions). Alternatively, if there were no RRC filters in the transmitter, we could incorporate raised cosine filters in FIG. 1 instead of RRC filters.

In any case, the purpose of the RRC filters is to perform pulse shaping to reduce the bandwidth of the over sampled symbol stream without introducing inter symbol interference and also to reduce noise outside the required bandwidth.

Referring to FIG. 4, each RRC filter 107a, 107b comprises 49 taps 401 in succession. Any number of taps could be chosen for the RRC filter (as long as the filter's frequency response meets the system requirements) but we prefer an odd number of taps so that the centre of the filter's impulse response will be a peak (rather than two equal values). Also, the greater the number of taps, the more attenuation there will be outside the desired bandwidth, but the greater the filter complexity and delay.

Referring once again to FIG. 1, after the RRC filters 107a and 107b, the I and Q signals are input into the differential decoder 109. The differential decoder comprises buffers 113a and 113b, multipliers 115a, 115b, 115c and 115d and adders 117a and 117b. The differential decoder 109 performs differential decoding of the incoming I and Q signals over a symbol span of one symbol, as follows:
Iₒᵤₜ(k)=Iᵢₙ(k)*Iᵢₙ(k−1)+Qᵢₙ(k)*Qᵢₙ(k−1)
Qₒᵤₜ(k)=Qᵢₙ(k)*Iᵢₙ(k−1)−Iᵢₙ(k)*Qᵢₙ(k−1)

This can be seen clearly from block 109 in FIG. 1. The Iᵢₙ(k) signal is input into buffer 113a, multiplier 115a and multiplier 115c. The Qᵢₙ(k) signal is input into buffer 113b, multiplier 115b and multiplier 115d. The buffer 113a outputs the I signal from the previous sample i.e. Iᵢₙ(k−1) and stores the Iᵢₙ(k) signal for the next iteration. Similarly, the buffer 113b outputs the Q signal from the previous sample i.e. Qᵢₙ(k−1) and stores the Qᵢₙ(k) signal for the next iteration. The output of multiplier 115a is I(k)*I(k−1), the output of the multiplier 115b is Q(k)*I(k−1), the output of multiplier 115c is I(k)*Q(k−1) and the output of multiplier 115d is Q(k)*Q(k−1). The outputs from multipliers 115a and 115d are input into adder 117a producing I(k)I(k−1)+Q(k)Q(k−1) i.e. Iₒᵤₜ(k). The outputs from multipliers 115b and 115c are input into adder 117b producing Q(k)I(k−1)−I(k)Q(k−1) i.e. Qₒᵤₜ(k).

After the differential decoder 109, the I and Q signals are input into the decision block 111. The decision rule might be something like

if Iₒᵤₜ>0, I=0 else I=1

If Qₒᵤₜ>0, Q=0 else Q=1

or any other suitable decision algorithm.

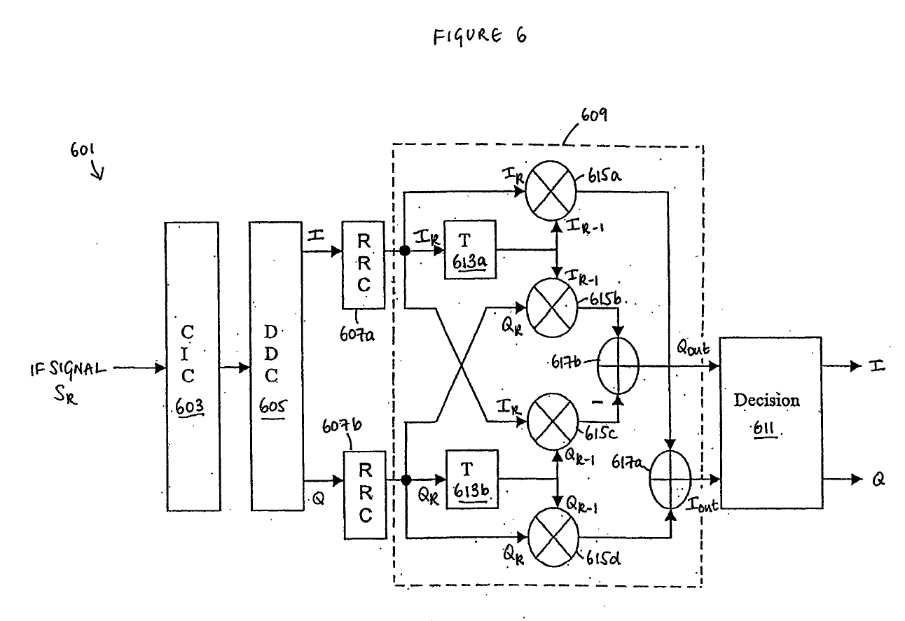

FIG. 5 shows performance of the demodulator of FIG. 1 under three different test conditions. In all three cases, the symbol rate was 2.048 Mbps, the intermediate frequency f_{IF} was 8.192 MHz and the CIC filter comprised two stages, with a decimation rate of R=4 (i.e. the decoding rate was always ¼ of the sampling rate). FIG. 5 is a plot of

$$\frac{Eb}{No}$$

expressed in dB on the x-axis versus bit error ratio (BER) on the y-axis. Eb is the energy in one bit and No is the noise power in a 1 Hz bandwidth. So the numerical ratio

$$\frac{Eb}{No}$$

is a form of signal to noise ratio. Thus, in FIG. 5, the BER is shown as a function of

$$\frac{Eb}{No}$$

i.e. in terms of the probability of error.

In graph A, the sampling rate fₛ was 131.072 MHz (i.e. 16 times the intermediate frequency) and the decoding rate was 32.768 MHz. In graph B, the sampling rate fₛ was 262.144 MHz (i.e. 32 times the intermediate frequency) and the decoding rate was 65.536 MHz. In graph C, the sampling rate fₛ was 524.288 MHz (i.e. 64 times the intermediate frequency) and the decoding rate was 131.072 MHz. FIG. 5 also shows the theoretical result—graph D.

It can be seen from FIG. 5 that the BER performance is better than that of prior art systems. In particular, this embodiment shows an improvement of 1.5 dB at a BER of 10⁻⁴ over the system described in “Digital Intermediate Frequency Demodulation Technique for Cellular Communication Systems”, Hideho TOMITA, Yukio YOKOYAMA, Toru MATSUKI, Global Telecommunications Conference, 1990, and Exhibition “Communications: Connecting the Future”, GLOBECOM '90, IEEE, which was mentioned earlier. In addition, the sampling rate is lower: up to only 16 times the intermediate frequency as opposed to at least 32 times the intermediate frequency (and possibly as high as 100 times the intermediate frequency) in prior art systems.

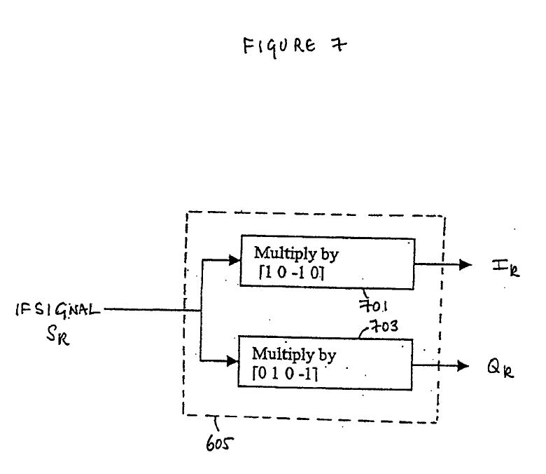

FIG. 6 shows a block diagram of a

$${f}_{s} = \frac{1}{{T}_{s}} ,$$

demodulator 601 according to a second embodiment of the invention. The FIG. 6 arrangement is similar to the FIG. 1 arrangement and includes a CIC filter 603, a DDC 605, RRC filters 607a and 607b, a differential decoder 609 and a decision block 611. As with FIG. 1, the input to the demodulator 601 is the 2-level IF signal from an IF hard limiter (not shown) and the outputs of the demodulator 601 are I and Q signals.

The FIG. 6 arrangement differs from the FIG. 1 arrangement in that the CIC filter 603 is upstream of the DDC 605. There are several advantages in swapping the positions of the CIC filter(s) and the DDC which will be discussed below.

The CIC filter 603 has a structure just like that shown in FIG. 3. There is an integrator portion comprising N integrator stages clocked at rate

$$\frac{π}{4} DQPSK$$

followed by a down sampler for reducing the clock rate by a factor R, followed by a comb portion comprising N comb stages clocked at rate

$$\frac{{f}_{s}}{R} = \frac{1}{{RT}_{s}} .$$

Once again, we choose R, M and N appropriately depending on the required frequency response of the CIC filter.

Obviously, with the arrangement of FIG. 6, only a single CIC filter is required since the I and Q signals have not yet been isolated; this is one advantage of the FIG. 6 arrangement. Also, the CIC filter can be greatly simplified as explained below.

In a CIC filter, the bit width growth is very fast. The output bit width can be shown to be:
Bₒᵤₜ=┌N log₂ RM+Bᵢₙ┐
where Bᵢₙ is the input bit width, Bₒᵤₜ is the output bit width, N is the number of CIC filter stages, R is the decimation ratio (i.e. the reduction of sampling rate as performed in the downsampler 305) and M is the delay in each comb unit. Therefore, the adders could have a rather large bit width. Moreover the Bₒᵤₜ bits are needed for every adder.

In order to compare the FIG. 1 and FIG. 6 arrangements fairly, we set R=8 for the FIG. 1 arrangement and R=4 for the FIG. 6 arrangement. For both arrangements, we assume that N=2 and M=1. For the arrangement of FIG. 1, the input to the CIC is the output of the DDC, which must be at least 4 bits to ensure acceptable performance in the DDC. Thus, for N=2, R=8, M=1 and Bᵢₙ=4, Bₒᵤₜ is 10. On the other hand, for the arrangement of FIG. 6, the input to the CIC is the output of the hard limiter which is just 1 bit. So, for N=2, R=4, M=1 and Bᵢₙ=1, Bₒᵤₜ is only 5. Thus, the output bit width can be reduced with the FIG. 6 arrangement, which is clearly advantageous.

Referring once again to FIG. 6, from the CIC filter 603, the signal is input to DDC 605. In the FIG. 6 arrangement, the clock rate of the DDC can be reduced since the CIC filter has already performed decimation; this is advantageous since it reduces power consumption. So, whereas previously the DDC clock rate was fₛ, the DDC clock rate can now be

$$\frac{4 {Rf}_{IF}}{R} = 4 {f}_{IF} .$$

Also, if we set the sampling frequency fₛ appropriately, the DDC structure can be simplified as will now be explained.

If we set the sampling frequency fₛ in the CIC to be 4Rf_{IF}, the sampling rate in the DDC is

$$\frac{{f}_{s}}{R} .$$

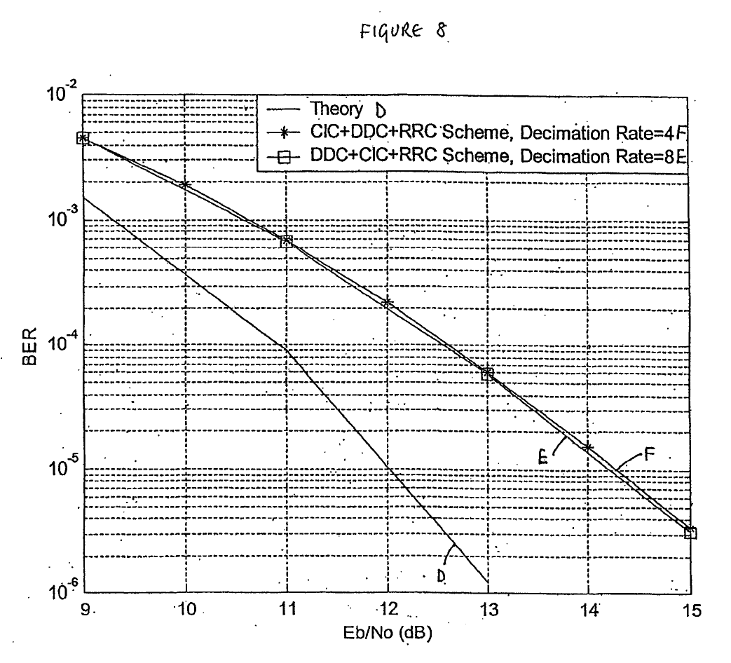

Considering the DDC structure shown in FIG. 2, we see that the I channel is produced by multiplying the incoming signal by cos{2πf_{IF}kTₛ} and the Q channel is produced by multiplying the incoming signal by sin{2πf_{IF}kTₛ}. However, since the DDC rate is four times that of the intermediate frequency, we can simplify the cosine and sine functions. This is because, over one cycle, cos x takes the values 1, 0, −1 and 0 and sin x takes the values 0, 1, 0 and −1. We can make use of this to simplify the DDC as shown in FIG. 7.

Referring to FIG. 7, the incoming signal Sₖ is multiplied by 1, 0, −1 and 0 at successive samples at block 701 to produce the I channel. The resulting I components are therefore of the forms:

Iₖ=Sₖ,0,−Sₖ,0 over a single cycle of the IF signal.

The incoming signal Sₖ is multiplied by 0, 1, 0 and −1 at successive samples at block 703 to produce the Q channel. The resulting Q components are therefore of the forms:

Qₖ=0,Sₖ,0,−Sₖ over a single cycle of the intermediate frequency signal.

(We may be able to make a similar simplification to the DDC in the FIG. 1 arrangement. However, this is less likely since the clock rate of the DDC in that arrangement has to be fₛ (because the DDC comes before the CIC filter) and it is unlikely that we can obtain acceptable performance with a sampling frequency only four times the intermediate frequency.)

Referring once again to FIG. 6, the I and Q signals are then input to RRC filters 607a and 607b respectively. The RRC filters are used for pulse shaping the symbol stream without the introduction of inter symbol interference and also for reduction of noise outside the desired bandwidth and each RRC filter may have the structure shown in FIG. 4.

From RRC filter 607a the I signal is input to the differential decoder 609 and from RRC filter 607b, the Q signal is input to the differential decoder 609. As before, the differential decoder comprises buffers 613a and 613b, multipliers 615a, 615b, 615c and 615d and adders 617a and 617b. The differential decoder 609 performs differential decoding of the incoming I and Q signals over a symbol span of one symbol, as follows:
Iₒᵤₜ(k)=Iᵢₙ(k)*Iᵢₙ(k−1)+Qᵢₙ(k)*Qᵢₙ(k−1)
Qₒᵤₜ(k)=Qᵢₙ(k)*Iᵢₙ(k−1)−Iᵢₙ(k)*Qᵢₙ(k−1)

After the differential decoder 609, the I and Q signals are input into the decision block 611, which produces I and Q outputs from the differentially decoded I and Q.

(In the FIG. 6 arrangement, we moved the CIC filter upstream of the DDC which brought several advantages. It would be possible to also bring the RRC upstream of the DDC. However, this arrangement will result in a complex filter before the DDC and the complexity of this complex filter is usually higher than the complexity of the two RRC filters. Also, to reject the out-of-band noise and higher frequency components of the DDC output, some kind of low pass filter may still be required after the DDC, even if a complex filter is used before the DDC. Therefore, although possible, this arrangement may not provide any additional advantages.)

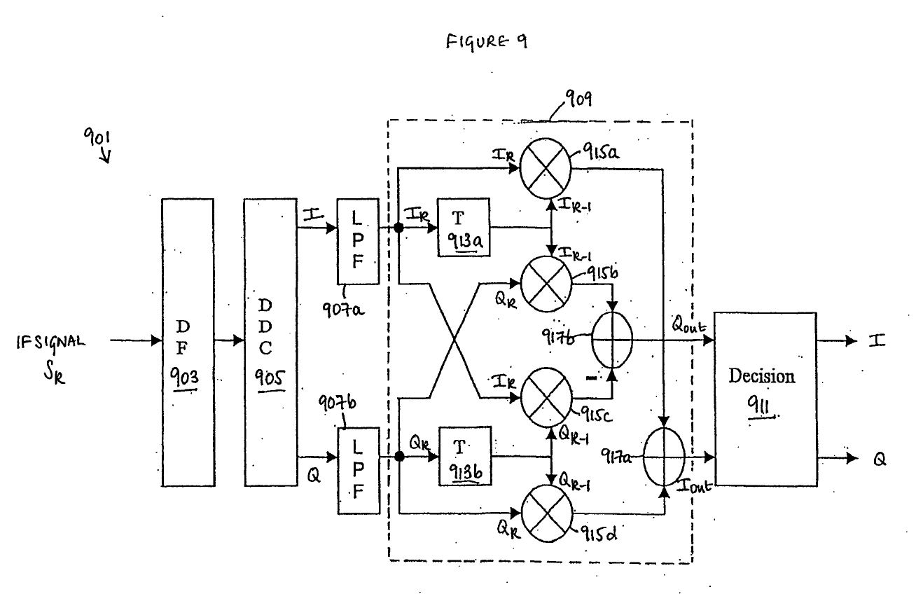

FIG. 8 shows performance of the demodulator of FIG. 1 and performance of the demodulator of FIG. 6 for a symbol rate of 2.048 Mbps, an intermediate frequency f_{IF} of 8.192 MHz and a sampling rate of 131.072 MHz (i.e. 16 times the intermediate frequency). Like FIG. 5, FIG. 8 is a plot of

$$\frac{Eb}{No}$$

expressed in dB on the x-axis versus bit error ratio (BER) on the y-axis. As before, for a fair comparison of the FIG. 1 and FIG. 6 arrangements, we set the decimation rate R to be 8 for the FIG. 1 arrangement (plot E) and we set the decimation rate R to be 4 for the FIG. 6 arrangement (plot F). Once again, the theoretical result D is shown for comparison.

It can be seen that the two embodiments (shown in FIGS. 1 and 6) produce almost exactly the same results. So, for both these embodiments, the BER performance shows an improvement over prior art BER performance and the sampling rate is lower.

FIG. 9 shows a block diagram of a

$$\frac{π}{4} DQPSK$$

demodulator 901 according to a third embodiment of the invention. The FIG. 9 arrangement is similar to that of FIG. 6 but the CIC filter 603 has been replaced by a generic decimation filter 903 and the RRC filters 607a and 607b have been replaced by simple low pass filters (LPF) 907a and 907b. Thus, the arrangement includes a Decimation Filter (DF) 903, a DDC 905, LPFs 907a and 907b, a differential decoder 909 and a decision block 911. As with FIGS. 1 and 6, the input to the demodulator 901 is the 2-level IF signal from an IF hard limiter (not shown) and the outputs of the demodulator 901 are I and Q signals.

The DF 903 is simply a general decimation filter for example a FIR filter. The purpose of the DF is to reduce the sampling rate.

From the DF 903, the signal is input to DDC 905. The DDC structure may have the structure shown in FIG. 2 to produce I and Q channels by multiplication by cos{2πf_{IF}kTₛ} and sin{2πf_{IF}kTₛ}respectively. Or, the DDC structure could be simplified like DDC 605 in FIG. 6. For example if the sampling rate of the DDC is four times the intermediate frequency, we can make use of the fact that the cosine function takes the values 1, 0, −1, 0 over each IF cycle and the sine function takes the values 0, 1, 0, −1 over each IF cycle.

From the DDC 905, the I and Q signals are input to the LPFs 907a and 907b. As already mentioned, the RRC filters in FIGS. 1 and 6 are used for pulse shaping and rejection of noise outside the required bandwidth. The pulse shaping was performed by the raised cosine function either by having RRC filter(s) in the transmitter side and RRC filter(s) in the receiver side, or by implementing the entire raised cosine function in the receiver side (i.e. doing no pulse shaping at all in the transmitter). If we now choose to do all the pulse shaping in the transmitter, we don't need to have even a RRC filter in the receiver. However, some kind of filter is still required to reduce noise outside the required bandwidth and interference, so we use simple low pass filters 907a and 907b. By performing all the pulse shaping on the transmitter side, the structure of the receiver can be simplified.

From LPF 907a, the I signal is input to the differential decoder 909 and from LPF 907b, the Q signal is input to the differential decoder 909. As before, the differential decoder comprises buffers 913a and 913b, multipliers 915a, 915b, 915c and 915d and adders 917a and 917b. The differential decoder 909 performs differential decoding of the incoming I and Q signals over a symbol span of one symbol, as follows:
Iₒᵤₜ(k)=Iᵢₙ(k)*Iᵢₙ(k−1)+Qᵢₙ(k)*Qᵢₙ(k−1)
Qₒᵤₜ(k)=Qᵢₙ(k)*Iᵢₙ(k−1)−Iᵢₙ(k)*Qᵢₙ(k−1)

After the differential decoder 909, the I and Q signals are input into the decision block 911.

Thus, in all the described embodiments, there is a lower power consumption because of the lower required sampling rate. Also, the performance in terms of BER is improved over prior art demodulators as shown in FIGS. 5 and 8.

1. Apparatus for demodulating a received hard limited differentially encoded phase shift keyed (DPSK) signal, the apparatus comprising:
a digital down converter (DDC) for generating an in-phase component I and a quadrature component Q of a received signal;
at least one decimator for reducing sampling frequency of the received signal;
at least one filter for reducing noise outside a required bandwidth; and
a differential decoder for performing differential detection of I and Q over a given symbol span.

2. Apparatus according to claim 1 wherein the DDC is upstream of the at least one decimator and the at least one decimator comprises one decimator for the I component and one decimator for the Q component.

3. Apparatus according to claim 1, wherein the DDC is downstream of the at least one decimator and the at least one decimator comprises only one decimator for the received signal.

4. Apparatus according to claim 1 wherein the DDC is arranged to generate the in-phase component I by multiplying the received signal by a cosine function and to generate the quadrature component Q by multiplying the received signal by a sine function.

5. Apparatus according to claim 4, wherein the DDC is arranged to operate at a frequency that is four times the frequency of the received signal and to simplify the cosine function to the values {1, 0, −1, 0} over each cycle of the received signal and to simplify the sine function to the values {0, 1, 0, −1} over each cycle of the received signal.

6. Apparatus according to claim 1 wherein the or each of the at least one decimator comprises a cascaded integrator comb (CIC) filter.

7. Apparatus according to claim 1 wherein the or each of the at least one decimator is a finite impulse response (FIR) filter.

8. Apparatus according to claim 1 wherein the or each of the at least one filter is arranged to perform pulse shaping of the received signal.

9. Apparatus according to claim 8 wherein the or each of the at least one filter comprises all or part of a raised cosine filter.

10. Apparatus according to claim 9 wherein the or each of the at least one filter comprises a root raised cosine (RRC) filter.

11. Apparatus according to claim 1 wherein the or each of the at least one filter comprises a low pass filter.

12. Apparatus according to claim 1 wherein the differential decoder is arranged to perform differential detection of I and Q over a symbol span of one symbol.

13. Apparatus according to claim 1 wherein the differential decoder comprises a decision block for converting the differentially decoded I into an I output and for converting the differentially decoded Q into a Q output, the I output and the Q output each taking a value of either 0 or 1.

14. Apparatus according to claim 13 wherein, if the differentially decoded I is greater than zero, the apparatus is arranged to provide an I output of 0 and, if the differentially decoded I is less than zero, the apparatus is arranged to provide an I output of 1.

15. Apparatus according to claim 13 wherein, if the differentially decoded Q is greater than zero, the apparatus is arranged to provide a Q output of 0 and, if the differentially decoded Q is less than zero, the apparatus is arranged to provide a Q output of 1.

16. Apparatus according to claim 1 further comprising a hard limiter for hard limiting the received DPSK signal.

17. Apparatus according to claim 1 wherein the apparatus is arranged to receive a received signal which is an intermediate frequency (IF) signal.

18. Apparatus according to claim 1 wherein the apparatus is arranged to receive a received signal which is
$$\frac{π}{4} DQPSK$$
modulated.

19. A receiver for differentially encoded phase shift keyed (DPSK) signals, the receiver comprising apparatus according to claim 1.

20. A method for demodulating a received hard limited differentially encoded phase shift keyed (DPSK) signal, the method comprising the steps of:
a) generating an in-phase component I and a quadrature component Q from a received signal;
b) reducing sampling frequency of the received signal;
c) reducing noise outside a required bandwidth; and
d) performing differential detection of I and Q over a given symbol span.

21. A method according to claim 20 wherein step a) is performed before step b) and step b) comprises the steps of reducing sampling frequency of the in-phase component I and reducing sampling frequency of the quadrature component Q.

22. A method according to claim 20 wherein step a) is performed after step b).

23. A method according to claim 20 wherein step a) comprises multiplying the received signal by a cosine function to generate the in-phase component I and multiplying the received signal by a sine function to generate the quadrature component Q.

24. A method according to claim 20 further comprising the step of pulse shaping the received signal.

25. A method according to claim 20 wherein step d) comprises performing differential detection of I and Q over a symbol span of one symbol.

26. A method according to claim 20 further comprising the steps of converting the differentially decoded I into an I output and converting the differentially decoded Q into a Q output, the I output and the Q output each taking a value of either 0 or 1.

27. A method according to claim 26 wherein, if the differentially decoded I is greater than zero, the I output is 0 and, if the differentially decoded I is less than zero, the I output is 1.

28. A method according to claim 26 wherein, if the differentially decoded Q is greater than zero, the Q output is 0 and, if the differentially decoded Q is less than zero, the Q output is 1.

29. A method according to claim 20 further comprising, before step a), the step of hard limiting the received DPSK signal.

30. A method according to claim 20 wherein the received signal is an intermediate frequency (IF) signal.

31. A method according to claim 20 wherein the received signal is
$$\frac{π}{4} DQPSK$$
modulated.

32. Apparatus for carrying out a method according to claim 20.

33. A receiver for differentially encoded phase shift keyed (DPSK) signals, for carrying out a method according to claim 20.
